(19) United States
(12) Patent Application Publication
(10) Pub. No.: US 2025/0355377 A1
(43) Pub. Date: Nov. 20, 2025

(54) SUBSTRATE PROCESSING SYSTEM, COMPUTATION APPARATUS, EXPOSURE APPARATUS, COMPUTATION METHOD, EXPOSURE METHOD, AND METHOD FOR MANUFACTURING ELECTRONIC DEVICE

(71) Applicant: NIKON CORPORATION, Tokyo (JP)

(72) Inventors: Isao SUGAYA, Kawasaki-shi (JP); Atsushi KAMASHITA, Komae-shi (JP); Hajime MITSUISHI, Yokohama-shi (JP)

(73) Assignee: NIKON CORPORATION, Tokyo (JP)

(21) Appl. No.: 19/285,319

(22) Filed: Jul. 30, 2025

Related U.S. Application Data
(63) Continuation of application No. PCT/JP2024/002824, filed on Jan. 30, 2024.

(30) Foreign Application Priority Data
Jan. 31, 2023 (JP) 2023-012405

(51) Int. Cl. G03F 9/00; G03F 7/20

(52) U.S. Cl. CPC G03F 9/7092; G03F 7/20; G03F 9/7015; G03F 9/7049

(57) ABSTRACT

A substrate processing system includes a substrate information acquiring unit configured to acquire substrate information including position information of a structure which is formed on a first substrate and a determination unit configured to determine an exposure condition for exposing a second substrate which is bonded to the first substrate to light on the basis of the acquired substrate information.

### TECHNICAL FIELD

The present invention relates to a substrate processing system, a computation apparatus, an exposure apparatus, a computation method, an exposure method, and an electronic device manufacturing method.

Priority is claimed on Japanese Patent Application No. 2023-012405, filed Jan. 31, 2023, the content of which is incorporated herein by reference.

### BACKGROUND ART

In the related art, there is a technique of manufacturing a stacked substrate by bonding substrate surfaces to each other (for example, see Patent Document 1)

However, in the aforementioned related art, there is a problem in that substrates cannot be bonded even when the substrates are positioned at the time of bonding.

### CITATION LIST

### Patent Document

Patent Document 1: Japanese Unexamined Patent Application, First Publication No. 2020-74369

### SUMMARY OF INVENTION

A substrate processing system according to the present invention includes a substrate information acquiring unit configured to acquire substrate information including position information of a structure which is formed on a first substrate and a determination unit configured to determine an exposure condition for exposing a second substrate which is bonded to the first substrate to light on the basis of the acquired substrate information.

A computation apparatus according to the present invention includes a substrate information acquiring unit configured to acquire substrate information including position information of a structure which is formed on a first substrate and a determination unit configured to determine an exposure condition for exposing a second substrate which is bonded to the first substrate to light on the basis of the acquired substrate information.

An exposure apparatus according to the present invention includes an exposure control unit configured to expose a second substrate which is bonded to a first substrate to light on the basis of an exposure condition which is determined on the basis of substrate information including position information of a structure formed on the first substrate.

A computation method according to the present invention includes a substrate information acquiring step of acquiring substrate information including position information of a structure which is formed on a first substrate and a determination step of determining an exposure condition for exposing a second substrate which is bonded to the first substrate to light on the basis of the acquired substrate information.

An exposure method according to the present invention includes an exposure control step of exposing a second substrate which is bonded to a first substrate to light on the basis of an exposure condition which is determined on the basis of substrate information including position information of a structure formed on the first substrate.

An electronic device manufacturing method according to the present invention includes a substrate information acquiring step of acquiring substrate information including position information of a structure which is formed on a first substrate, a determination step of determining an exposure condition for exposing a second substrate which is bonded to the first substrate to light on the basis of the acquired substrate information, an exposure control step of exposing the second substrate to light on the basis of the determined exposure condition, and a stacking step of overlapping the first substrate and the second substrate.

### BRIEF DESCRIPTION OF DRAWINGS

FIG. 1 A diagram illustrating an example of a functional configuration of a substrate processing system according to a first embodiment.

FIG. 2 A diagram illustrating an example of a multilayered wiring structure according to the first embodiment.

FIG. 3 A diagram illustrating an example of a stacked substrate after bonding according to the first embodiment.

FIG. 4 A diagram illustrating an example of a functional configuration of an exposure apparatus according to the first embodiment.

FIG. 5 A sequence diagram illustrating an example of a series of operations in the substrate processing system according to the first embodiment.

FIG. 6 A schematic diagram illustrating an example of a substrate exposed by an exposure apparatus according to the first embodiment.

FIG. 7 A diagram illustrating a problem to be solved in a second embodiment.

FIG. 8 A sequence diagram illustrating an example of a series of operations in an exposure apparatus according to the second embodiment.

FIG. 9 A schematic diagram illustrating an example of a substrate exposed by the exposure apparatus according to the second embodiment.

FIG. 10 A sequence diagram illustrating an example of a series of operations in a substrate processing system according to a third embodiment.

FIG. 11 A sequence diagram illustrating an example of a series of operations in a substrate processing system according to a fourth embodiment.

FIG. 12 A schematic diagram illustrating an interposer wafer according to the fourth embodiment.

### DESCRIPTION OF EMBODIMENTS

Hereinafter, embodiments of the present invention will be described with reference to the accompanying drawings. Embodiments described below are only examples, and embodiments of the present invention are not limited to the following embodiments.

### First Embodiment

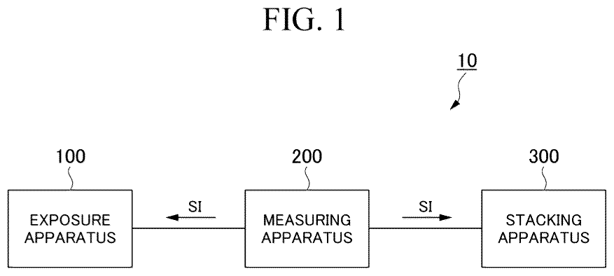

A first embodiment will be described below with reference to FIGS. 1 to 6.

FIG. 1 is a diagram illustrating an example of a functional configuration of a substrate processing system according to the first embodiment. An example of a functional configuration of a substrate processing system 10 will be described below with reference to the drawing. The substrate processing system 10 forms a desired structure on one or more substrates (wafer) P, permanently bonds the substrate P having the structure formed thereon and another substrate P which form a pair by overlapping the two substrates, and manufactures a multilayered substrate.

The substrate processing system 10 includes an exposure apparatus 100, a measuring apparatus 200, and a stacking apparatus 300.

The exposure apparatus 100 performs an exposure process on a substrate P. A photosensitive material (for example, a photoresist) is applied in advance onto the surface of the substrate P by a predetermined processing apparatus. The exposure apparatus 100 exposes the surface of the substrate P to a desired pattern by irradiating a photosensitive surface onto which the photosensitive material has been applied with an optical pattern. The exposure apparatus 100 forms a latent image corresponding to the desired pattern by exposing the surface of the substrate P to the desired pattern. The substrate P on which the latent image has been formed is developed by a processing apparatus which is not illustrated, and thus a structure is formed on the surface of the substrate P. Examples of the structure formed on the surface of the substrate P may include circuit elements, circuit networks, and connection terminals.

The exposure apparatus 100 may expose one or more alignment marks AM to light in addition to the desired pattern. The structure formed on the surface of the substrate P may include an alignment mark AM. A plurality of pattern areas (shot areas) in which a pattern is formed and one or more alignment marks AM accessory to the pattern areas are formed on the surface of the substrate P. The alignment mark AM is measured by at last one of the exposure apparatus 100, the measuring apparatus 200, and the stacking apparatus 300. The measured alignment mark AM is used as a reference position for stacking the exposed substrate P with another substrate.

The alignment mark AM may be measured by the exposure apparatus 100 and thus may be used as a reference position for exposure.

The measuring apparatus 200 measures position information of the structure formed on the substrate P as a result of exposure from the exposure apparatus 100. In the substrate P, a distortion such as a magnification distortion, an orthogonal distortion, or a nonlinear distortion may be caused in an exposure process performed by the exposure apparatus 100 or a processing step performed by other processing apparatuses (for example, a film forming apparatus such as a sputtering apparatus or a chemical vapor deposition (CVD) apparatus, an application apparatus applying a photosensitive material such as a photoresist, an exposure apparatus, a developing apparatus, an etching apparatus, or a thermal processing apparatus such as an annealing apparatus). The measuring apparatus 200 measures information in various distortions caused in the substrate P as will be described later. In this way, the measuring apparatus 200 measures position information of a structure formed on the substrate P carried out of the exposure apparatus 100 and information on various distortions caused in the substrate P.

A measurement control unit of the measuring apparatus 200, the exposure apparatus 100, and the stacking apparatus 300 are connected to each other via a local area network (LAN) and communicate with each other. A control device that controls the substrate processing system 10 as a whole is connected to the LAN.

The measuring apparatus 200 measures a plurality of alignment marks AM on the substrate P and measures a distortion of the substrate P.

For example, the measuring apparatus 200 detects at least one alignment mark AM for each of a plurality of shot areas partitioned on the substrate. In the present embodiment, the measuring apparatus 200 may measure positions of all the alignment marks AM provided on the substrate P. The measuring apparatus 200 calculates position information of each alignment mark AM on the basis of the measurement information and performs an enhanced global alignment (EGA) operation using the position information of the alignment marks AM. The EGA operation means a statistical operation of calculating parameters of a model expression for expressing a correction value of positional coordinates of the alignment marks AM using a statistical operation such as a least square method on the basis of information of a difference between a designed value and a measured value of the positional coordinates of the alignment mark AM after measuring the alignment marks AM.

By calculating a result of the EGA operation using a statistical operation such as a least square method, it is possible to accurately calculate a linear component and a nonlinear component of an initial distortion of the substrate P. The measuring apparatus 200 transmits information of the calculated linear component and the calculated nonlinear component of the initial distortion of the substrate P to a computation apparatus 1000 which will be described later. The measuring apparatus 200 may transmit only information of the nonlinear component of the initial distortion of the substrate P to the computation apparatus 1000.

The measuring apparatus 200 may have a reference coordinate system and measure absolute coordinates of the alignment marks AM on the substrate P in the reference coordinate system. The measuring apparatus 200 may detect absolute coordinates of other marks on the substrate P in addition to the alignment marks AM.

The measuring apparatus 200 may measure the absolute coordinates of the alignment marks AM on the substrate P and transmit the calculated position information of the alignment marks AM to an exposure apparatus for exposing the substrate to a pattern. In this case, the exposure apparatus sets an exposure condition on the basis of the received position information and uses the exposure condition to expose a substrate other than the substrate P to light.

When a measurement target is a stacked body, the measuring apparatus 200 may measure absolute coordinates of alignment marks AM of at least one substrate P (for example, an uppermost substrate) out of a plurality of substrates P constituting the stacked body and calculate position information thereof. For example, the measuring apparatus 200 may measure an overlay mark used to measure a relative position between two substrates P instead of at least one substrate P of a plurality of substrates P constituting the stacked body. In this case, the structure may include an overlay mark. The measuring apparatus 200 may transmit the calculated position information of the alignment marks AM to an exposure apparatus for exposing at least one substrate of the stacked body to patterned light. The exposure apparatus sets an exposure condition on the basis of the received position information and uses the exposure condition anew to expose at least one substrate of the stacked body to patterned light.

The measuring apparatus 200 may measure a pattern in a shot area or a part of the pattern instead of the alignment marks in addition to the positions of all the alignment marks AM provided on the substrate P.

The measuring apparatus 200 may increase the number of measuring points in an outer circumferential area of the substrate P with respect to the number of measuring points in a central area of the substrate P and accurately measure a distortion of the substrate P in the outer circumferential area of the substrate P. In the present embodiment, since the positions of all the alignment marks AM provided on the substrate P are measured, parts of patterns in more shot areas are measured in the outer circumferential area of the substrate P. It is possible to increase the number of measuring points by measuring parts of patterns in a plurality of shot areas in the outer circumferential area of the substrate P. When the number of measuring points in the outer circumferential area of the substrate P is increased, an overlay mark in the outer circumferential area of the substrate P may be measured. The overlay mark may be measured along with parts of patterns in the shot areas.

Similarly, the measuring apparatus 200 may measure parts of patterns in more shot areas in addition to the alignment marks AM in an area in which reproducibility of a distortion of the substrate P is high or an area in which a distortion of the substrate P is steep.

The measuring apparatus 200 may measure bending of the substrate P which has been exposed to light by the exposure apparatus 100 and estimate an amount of distortion of a stacked substrate after the stacking apparatus 300 has bonded two substrates P using the result of measurement.

The stacking apparatus 300 bonds two substrates P by stacking a substrate P exposed to light by the exposure apparatus 100 and measured by the measuring apparatus 200 and another substrate P. More specifically, the stacking apparatus 300 bonds two substrates P by stacking a substrate P including a structure formed on the surface thereof and another substrate P in which a structure overlapping the structure formed on the surface of the substrate P is formed on the surface thereof. The overlapping structures may be conductors such as circuit elements, circuit networks, and connection terminals. A base of a substrate P on which a structure is formed may be a silicon wafer, a compound semiconductor wafer, a glass substrate, or the like.

Regarding substrates P which are bonded by the stacking apparatus 300, each substrate P may have a stacked structure which is formed by stacking a plurality of substrates in advance.

An alignment mark AM is an example of a structure formed on the surface of a substrate P. In the present embodiment, the stacking apparatus 300 uses the alignment marks AM as a reference position for bonding two substrates P.

The stacking apparatus 300 includes, for example, two microscopes which are not illustrated and detects the alignment marks AM provided in each of two substrates P to be bonded. By detecting alignment marks AM on the substrates P using two microscopes between which a relative position is known, the relative position between two substrates P to be bonded is identified. The stacking apparatus 300 bonds the two substrates P to be bonded on the basis of the identified relative position.

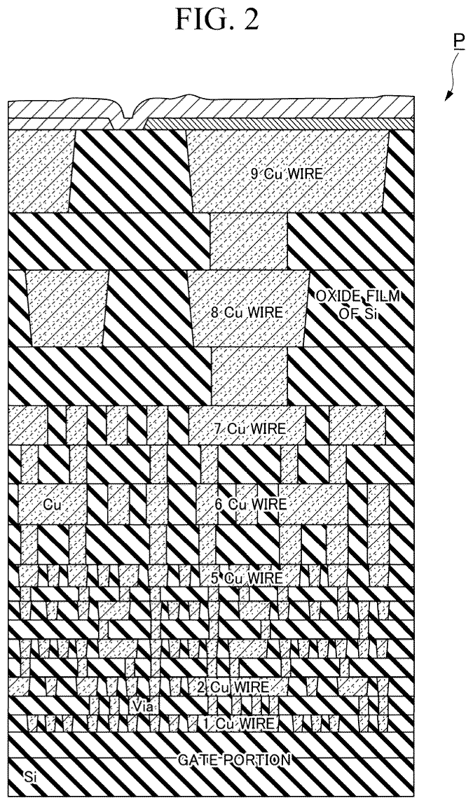

FIG. 2 is a diagram illustrating an example of a multilayered wiring structure according to the first embodiment. An example of a multilayered wiring structure of a substrate P will be described below with reference to the drawing. The drawing illustrates an example in which a substrate P has a nine-layered copper wiring structure.

A gate portion illustrated in the lower part of the drawing is a silicon wafer. A layer (layer) formed just above the gate portion is referred to as a first layer L1, and layers formed above the first layer are sequentially referred to as a second layer L2, . . . , a ninth layer L9 from the lowermost layer. The layers from the first layer L1 to the ninth layer L9 are insulated by interlayer insulating films. When copper wires formed in the layers are connected between the layers, elements formed in the layers are connected by forming via-holes (contact holes) Via in the interlayer insulating films.

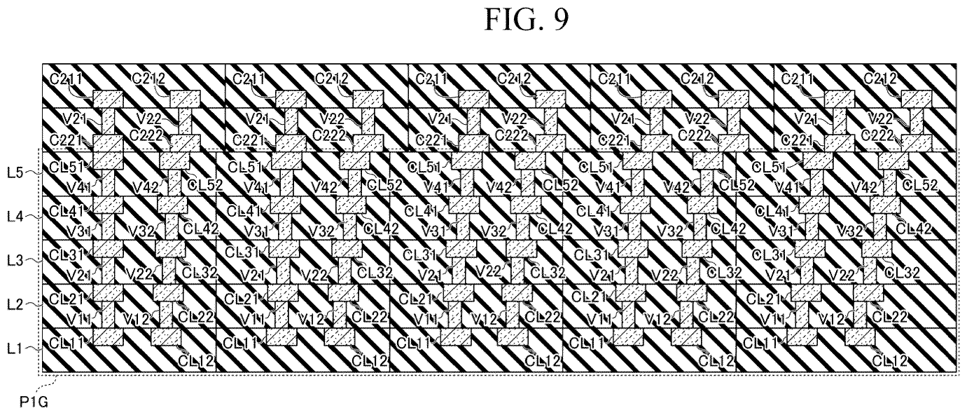

The substrate processing system 10 positions a structure formed in the uppermost layer of the substrate P (a ninth layer L9 in the example illustrated in FIG. 9) and a structure formed in the uppermost layer of the corresponding substrate P and bonds the substrates.

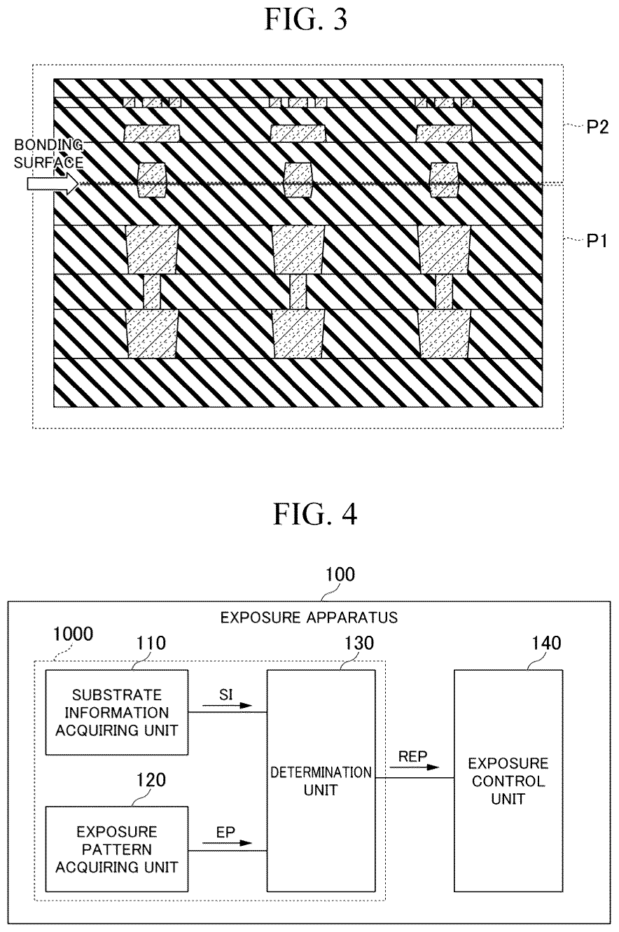

FIG. 3 is a diagram illustrating an example of a stacked substrate after bonding according to the first embodiment. An example of a wiring structure when the substrates P are bonded will be described below with reference to the drawing. In an example illustrated in the drawing, a first substrate P1 and a second substrate P2 are bonded to each other in the uppermost layers thereof. The stacking apparatus 300 positions the uppermost layer of the first substrate P1 and the uppermost layer of the second substrate P2 and bonds the substrates using an intermolecular force between bonding surfaces thereof.

In the following description, the first substrate P1 may be referred to as a lower wafer, and the second substrate P2 may be referred to as an upper wafer. The names of the lower wafer and the upper wafer are not distinguished on the basis of functions or the like of the first substrate P1 and the second substrate P2. That is, one substrate P bonded by the stacking apparatus 300 is referred to as a lower wafer, and the other substrate P is referred to as an upper wafer. One of the lower wafer and the upper wafer may be manufactured earlier, and a wafer which is manufactured earlier may be referred to as an upper wafer.

Here, two substrates P which are bonded by the substrate processing system 10 may have different functions. For example, when it is intended to manufacture one semiconductor device having two different functions, it may be preferable to manufacture a substrate P for each function and then to bond the manufactured substrates. As two functions, for example, one may be a logic circuit, and the other may be a memory circuit. One may be a photo diode, and the other may be a logic circuit. With the substrate processing system 10, since substrates P having two different functions are bonded, the substrates P are manufactured by manufacturing processes suitable for the functions and then can be bonded into one substrate.

FIG. 4 is a diagram illustrating an example of a functional configuration of the exposure apparatus according to the first embodiment. An example of the functional configuration of the exposure apparatus 100 will be described below with reference to the drawing. The exposure apparatus 100 exposes a substrate P to light on the basis of substrate information SI. In this example, substrate information SI is position information measured by the measuring apparatus 200.

The exposure apparatus 100 includes a substrate information acquiring unit 110, an exposure pattern acquiring unit 120, a determination unit 130, and an exposure control unit 140 as the functional configuration. The exposure apparatus 100 includes a central processing unit (CPU) and a storage device such as a read only memory (ROM) or a random access memory (RAM) (not illustrated) which are connected to a bus and serves as an apparatus including the substrate information acquiring unit 110, the exposure pattern acquiring unit 120, the determination unit 130, and the exposure control unit 140 by executing an exposure program.

All or some of the functions of the exposure apparatus 100 may be realized by hardware such as an application-specific integrated circuit (ASIC), a programmable logic device (PLD), or a field-programmable gate array (FPGA).

In the following description, the substrate information acquiring unit 110, the exposure pattern acquiring unit 120, and the determination unit 130 are also referred to as a computation apparatus 1000.

The substrate information acquiring unit 110 acquires substrate information SI. The substrate information SI is position information which is used to form a structure on a second substrate P2 to be bonded to a first substrate P1 and includes position information of a structure formed on the first substrate P1. The substrate information SI may include position information of the alignment marks AM, position information of patterns in shot areas or parts of the patterns, position information of an overlay mark, information of distortions in the surface of the substrate P, and information of distortions (for example, bending) in a direction crossing the surface of the substrate P. The substrate information SI is acquired by measuring the surface of the first substrate P1 using the measuring apparatus 200.

The exposure apparatus 100 corrects the exposure pattern EP on the basis of the acquired substrate information SI and forms a structure on the second substrate P2 on the basis of the post-correction exposure pattern REP. That is, the exposure apparatus 100 sets an exposure condition for exposing the second substrate P2 to light on the basis of the substrate information SI. The substrate information SI includes position information used to form a structure on the second substrate P2. In other words, the substrate information SI includes information for correcting the exposure pattern EP when the exposure apparatus 100 exposes the second substrate P2 to light.

Regarding the exposure apparatus 100, a first exposure apparatus for exposing the first substrate P1 to light and the exposure apparatus 100 for exposing the second substrate to light may be different exposure apparatuses. In this case, the substrate information SI is information which is obtained by measuring a structure formed on the first substrate P1 by the first exposure apparatus using the measuring apparatus 200.

In the following description, it is assumed that a first exposure apparatus 100A for exposing the first substrate P1 to light and a second exposure apparatus 100B for exposing the second substrate P2 to light are different exposure apparatus 100, but may be the same exposure apparatus. This is because there is a likelihood of individual unevenness of each substrate even when substrates are exposed to light using the same exposure apparatus. When a process such as film formation has been performed, unevenness in distortion of individual substrates is expected to increase.

The exposure pattern acquiring unit (pre-correction exposure pattern acquiring unit) 120 acquires an exposure pattern EP. The exposure pattern EP includes desired pattern information with which a substrate P is exposed to light by the exposure apparatus 100. The exposure pattern acquiring unit 120 acquires the exposure pattern EP which is a preset pre-correction exposure pattern. The exposure pattern EP acquired by the exposure pattern acquiring unit 120 includes information on an optical pattern (a projection pattern image) on a wafer. The exposure pattern acquiring unit 120 acquires the exposure pattern EP, for example, from an input device which is not illustrated. The pre-correction exposure pattern may be an exposure pattern not including information on a distortion.

The determination unit 130 determines an exposure pattern with which the second substrate P2 is exposed to light, that is, an exposure condition for exposing the second substrate P2 to light, on the basis of the acquired substrate information SI. Specifically, the determination unit 130 corrects the exposure pattern EP which is the acquired pre-correction exposure pattern on the basis of the acquired substrate information SI. The determination unit 130 determines a post-correction exposure pattern REP by correcting the pre-correction exposure pattern. The determination unit 130 may specifically perform correction using information on a distortion of the first substrate P1 (individual measured values corresponding to points on the surface of the substrate) included in the substrate information SI. The determination unit 130 may correct the exposure pattern EP by applying the information on a distortion of the first substrate P1 included in the substrate information SI to a predetermined approximate expression.

When the first exposure apparatus 100A for exposing the first substrate P1 to light and the second exposure apparatus 100B for exposing the second substrate P2 to light are different exposure apparatuses 100, the determination unit 130 corrects the exposure pattern EP for exposing the second substrate P2 to light in the second exposure apparatus 100B on the basis of the substrate information SI which is acquired as a result measured after the first substrate Pl is exposed to light by the first exposure apparatus 100A.

When the first exposure apparatus 100A for exposing the first substrate P1 to light and the second exposure apparatus 100B for exposing the second substrate P2 to light are different apparatuses or when the first substrate P1 and the second substrate P2 are exposed to light in fabrication laboratories, the determination unit 130 may determine an exposure position, that is, the exposure pattern EP, in consideration of deformation of a substrate due to a difference in manufacturing environmental conditions (for example, temperature and humidity) between the exposure apparatuses or between the fabrication laboratories.

Determination of an exposure pattern EP (that is, correction of an exposure pattern) which is performed by the determination unit 130 will be described below in detail. In the present embodiment, the correction of an exposure pattern includes adjustment of a position of the exposure pattern and a shape of the exposure pattern. The position of an exposure pattern is a position at which the exposure apparatus 100 exposes the second substrate P2 to light. The correction of the position of the exposure pattern includes, for example, shift of the exposure pattern or rotation of the exposure pattern. The correction of the position of the exposure pattern may include, for example, a combination of shift of the exposure pattern and rotation of the exposure pattern. The shape of the exposure pattern is a shape of a pattern with which the exposure apparatus 100 exposes the second substrate P2 to light. The correction of the shape of the exposure pattern may include, for example, enlargement, reduction, and modification. The correction of the shape of the exposure pattern may include, for example, a combination of enlargement, reduction, and modification.

The determination unit 130 may correct the exposure pattern EP in the units of shots or may correct the exposure pattern EP in the units of chips. That is, the post-correction exposure pattern REP corrected by the determination unit 130 may be provided in the units of shots or in the units of chips. The unit of a shot is a range in which the exposure apparatus 100 can perform exposure instantaneously. For example, when the exposure apparatus 100 performs maskless exposure using a digital micromirror device (DMD) which is not illustrated, the unit of a shot is the unit of a pattern which can be instantaneously projected by the DMD. The unit of a chip is a unit of a semiconductor device when a plurality of semiconductor devices are manufactured on the surface of the substrate P.

The determination unit 130 may correct the exposure pattern EP in the unit of a wafer (the unit of a substrate P). That is, the post-correction exposure pattern REP may be a unit of a wafer.

The determination unit 130 may correct the exposure pattern EP in combination of correction in the unit of a shot and correction in the unit of a chip. In this case, the determination unit 130 corrects both a pattern for exposing one shot and a pattern for exposing one chip.

When the determination unit 130 corrects an exposure pattern EP, different correction methods may be used when the exposure apparatus 100 performs correction using a mask and when the exposure apparatus 100 performs correction without using a mask (that is, maskless exposure). Specifically, when the exposure apparatus 100 performs exposure using a mask, the correction of the position of the exposure pattern may include adjustment of a stage position at the time of exposure, adjustment of a mask position, or exchange of a mask. The adjustment of a stage position includes shift or rotation of the stage position. When the exposure apparatus 100 performs exposure using a mask, the correction of a shape of a pattern may include enlargement and reduction with a change in magnification of a lens, adjustment of a relative position between a stage and a mask at the time of scanning exposure, modification of a pattern with control of a magnification of a lens, rotation of a pattern (a shot), rotation of a mask, enlargement and reduction of a mask, modification of a mask, and a combination thereof.

When the exposure apparatus 100 performs exposure without using a mask, the correction of the position of the exposure pattern may include inputting of information of a corrected pattern position or adjustment of a stage position or a mask position at the time of exposure. When the exposure apparatus 100 performs exposure without using a mask, the correction of the pattern shape may include inputting of information of a corrected pattern position or adjustment of a pattern generation device or an exposure optical system.

The exposure control unit 140 performs control for exposing the second substrate P2 to light on the basis of the post-correction exposure pattern REP which is a corrected exposure pattern EP. The corrected exposure pattern EP is an exposure pattern determined by the determination unit 130, that is, a post-correction exposure pattern REP. In other words, the exposure apparatus 100 exposes the second substrate P2 to light on the basis of the exposure pattern determined by the determination unit 130.

When the first exposure apparatus 100A for exposing the first substrate P1 to light and the second exposure apparatus 100B for exposing the second substrate to light are different exposure apparatuses, the exposure control unit 140 performs control for exposing the second substrate P2 different from the first substrate P1 to light.

When the exposure apparatus 100 performs maskless exposure using a DMD, the exposure control unit 140 performs control of a light source for irradiating the DMD, tilt control of micromirrors provided in the DMD, movement control of a stage on which the second substrate P2 is mounted, and the like. Particularly, the exposure control unit 140 performs control for tilt of each micromirror provided in the DMD on the basis of the post-correction exposure pattern REP.

In the example illustrated in FIG. 4, the computation apparatus 1000 is assembled into the exposure apparatus 100, but the computation apparatus 1000 may be provided as an apparatus different from the exposure apparatus 100. When the computation apparatus 1000 is provided as an apparatus different from the exposure apparatus 100, the computation apparatus 1000 may be included in the substrate processing system 10 and may be connected to at least one of the exposure apparatus 100, the measuring apparatus 200, and the stacking apparatus 300. When the computation apparatus 1000 is provided as an apparatus different from the exposure apparatus 100, the computation apparatus 1000 may receive a measurement result from the measuring apparatus 200 and transmit an exposure pattern determined by the determination unit 130 to the exposure apparatus 100. In this way, the computation apparatus 1000 may serve as a control device for controlling the substrate processing system 10 as a whole.

In the illustrated example, the computation apparatus 1000 includes the substrate information acquiring unit 110, the exposure pattern acquiring unit 120, and the determination unit 130, but the computation apparatus 1000 may include only the substrate information acquiring unit 110 and the determination unit 130.

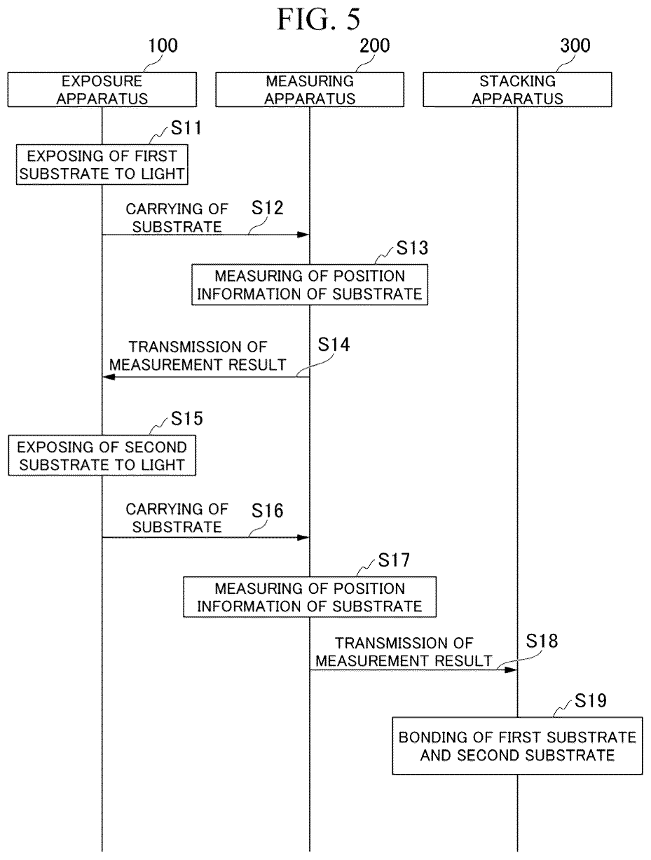

FIG. 5 is a sequence diagram illustrating an example of a series of operations in the substrate processing system according to the first embodiment. A series of operations in the substrate processing system 10 will be described below with reference to the drawing. In the present embodiment, one of a first substrate P1 on which first exposure is to be performed and a second substrate P2 on which second exposure is to be performed may be a stacked substrate. For the purpose of convenience, both the first substrate P1 and the second substrate P2 are exposed to light by the shared exposure apparatus 100, but the first substrate P1 and the second substrate P2 may be exposed to light by different exposure apparatuses 100.

In the present embodiment, it is assumed that the substrate processing system 10 measures position information of an uppermost layer of the first substrate P1 and exposes an uppermost layer of the second substrate P2 to light after having manufactured the first substrate P1.

(Step S11) The exposure apparatus 100 performs first exposure on the first substrate P1. A structure is formed on a substrate surface by forming a latent image on the first substrate P1 through the first exposure using the exposure apparatus 100 and then performing development or the like thereon using other processing apparatuses which are not illustrated.

(Step S12) The first substrate P1 in which the structure has been formed on the substrate surface is carried to the measuring apparatus 200 using a predetermined method.

(Step S13) The measuring apparatus 200 measures position information of the structure formed on the substrate surface of the carried first substrate P1. The position information on the substrate surface measured by the measuring apparatus 200 includes a distortion caused when the substrate surface is exposed to light by the exposure apparatus 100 or a distortion caused when development or the like is performed thereon using the other processing apparatuses.

(Step S14) The measuring apparatus 200 transmits substrate information SI including a result of measurement of the position information on the substrate surface of the first substrate P1 to the exposure apparatus 100. The substrate information SI may include identification information for identifying the first substrate P1 or information on treatment performed on the first substrate P1 in addition to the result of measurement.

(Step S15) The exposure apparatus 100 acquires the substrate information SI including the result of measurement of the position information on the substrate surface of the first substrate P1 from the measuring apparatus 200. The exposure apparatus 100 performs second exposure on the second substrate P2 on the basis of the acquired information.

Here, when a distortion is caused in the first substrate P1 and the first substrate P1 and the second substrate P2 are bonded to each other, their positions may not match accurately and bonding failure may occur. Bonding failure may be, for example, that desired conductors are not connected due to positional mismatch and an intentional open circuit is formed when a conductor formed on the first substrate P1 and a conductor formed on the second substrate P2 are bonded. Bonding failure may be that a short circuit is formed by unintentionally bringing a conductor bonded to the first substrate P1 and a conductor bonded to the second substrate P2 into contact with each other.

The exposure apparatus 100 curbs occurrence of bonding failure by correcting a position of a structure formed on the second substrate P2 according to the position information of the structure formed on the first substrate P1.

The exposure apparatus 100 may apply information of the first substrate P1 forming a pair along with the second substrate P2 to the second substrate P2 using a predetermined method when the second substrate P2 is exposed to light.

The exposure apparatus 100 may predict at least one of the amount of modification caused in the first substrate P1, an amount of positional mismatch, and an amount of distortion while bonding on the basis of the position information of the structure formed on the first substrate P1. In this case, the exposure apparatus 100 may estimate an amount of positional mismatch acquired as a result of bonding the first substrate P1 and the second substrate P2 on the basis of the predicted amount and determine an exposure pattern for the second substrate P2 such that the estimated amount of positional mismatch decreases. In this case, it is preferable that position information of the uppermost layer of the first substrate P1 be used as the position information of the structure formed on the first substrate P1.

The exposure apparatus 100 may measure an amount of positional mismatch between the first substrate P1 and the second substrate P2 after bonding in advance using the measuring apparatus 200, an IR measuring apparatus, or the like and determine an exposure pattern for at least one of the first substrate P1 and the second substrate P2 which are next bonded such that the amount of positional mismatch decreases using the measurement result.

When a distortion caused in the first substrate P1 or the second substrate P2 while bonding is known, the exposure apparatus 100 may determine the exposure pattern for both or one of the first substrate P1 and the second substrate P2 in consideration of the amount of correction for correcting positional mismatch due to the distortion.

(Step S16) The second substrate P2 in which a structure is formed on the substrate surface thereof is carried to the measuring apparatus 200 using a predetermined method.

(Step S17) The measuring apparatus 200 measures position information of the structure formed on the substrate surface of the carried second substrate P2. The position information on the substrate surface measured by the measuring apparatus 200 includes a distortion caused when exposure is performed by the exposure apparatus 100 or a distortion caused when development or the like is performed by the other processing apparatuses.

(Step S18) The measuring apparatus 200 transmits substrate information SI including the result of measurement of the position information on the substrate surface of the second substrate P2 to the stacking apparatus 300. The substrate information SI may include identification information for identifying the second substrate P2 or information on treatment performed on the second substrate P2 in addition to the result of measurement. The substrate information SI may include information on the result of measurement of the position information on the substrate surface of the first substrate P1 forming a pair along with the second substrate P2.

(Step S19) The first substrate P1 and the second substrate P2 are carried to the stacking apparatus 300. The stacking apparatus 300 bonds the first substrate P1 and the second substrate P2 by stacking the carried substrates. The stacking apparatus 300 may acquire information on substrates serving as a pair at the time of bonding from the substrate information SI or using other methods.

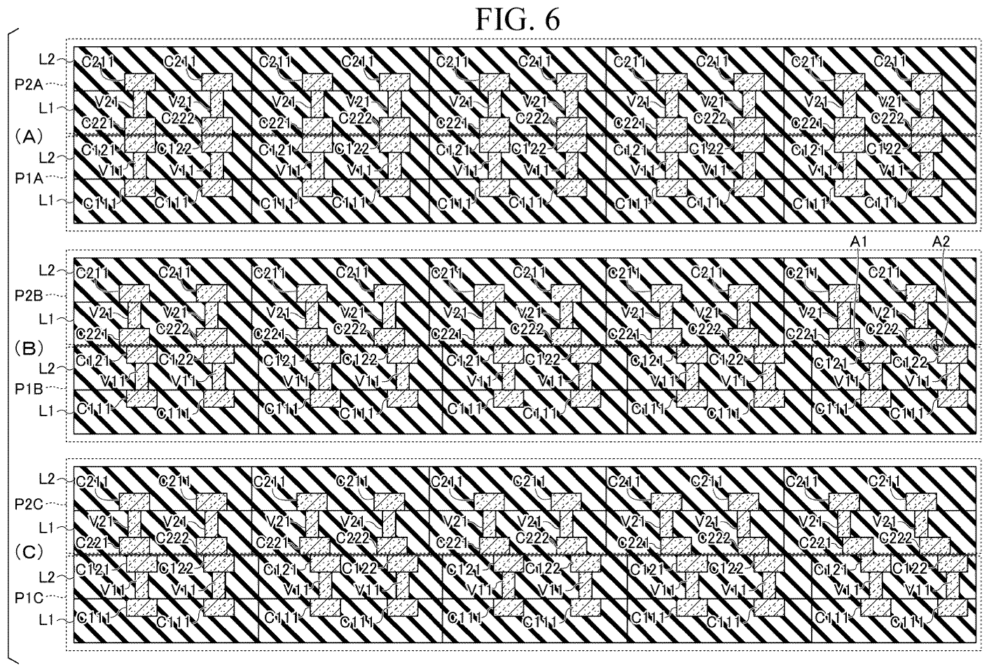

FIG. 6 is a diagram schematically illustrating an example of a substrate exposed to light by the exposure apparatus according to the first embodiment. Advantageous effects when exposure is performed using a post-correction exposure pattern REP by the exposure apparatus 100 according to the first embodiment will be described below with reference to FIGS. 6(A) to 6(C). FIG. 6(A) illustrates an example in which a first substrate P1A which is an example of the first substrate P1 and a second substrate P2A which is an example of the second substrate P2 are bonded, FIG. 6(B) illustrates an example in which a first substrate P1B which is an example of the first substrate P1 and a second substrate P2B which is an example of the second substrate P2 are bonded, and FIG. 6(C) illustrates an example in which a first substrate P1C which is an example of the first substrate P1 and a second substrate P2C which is an example of the second substrate P2 are bonded.

In the examples described with reference to FIG. 6, each of the first substrate P1 and the second substrate P2 includes a first layer L1 and a second layer L2, and the second layers L2 are uppermost layers thereof. The first substrate P1 includes a plurality of conductors C111 in the first layer L1 and includes a plurality of conductors C121 in the second layer L2. The conductors C111 in the first layer L1 and the conductors C121 in the second layer L2 are connected via contact holes V11. The second substrate P2 includes a plurality of conductors C211 in the first layer L1 and includes a plurality of conductors C221 in the second layer L2. The first layer L1 and the second layer L2 are connected via contact holes V21.

In the second layers L2 which are the uppermost layers of the first substrate P1 and the second substrate P2, the conductors C121 and the conductors C221 are bonded to each other.

FIG. 6(A) is a diagram schematically illustrating an example in which a distortion is not caused in any of the first substrate PIA and the second substrate P2A. In this case, since the first substrate P1A and the second substrate P2A are disposed according to a reference, both substrates can be bonded to each other without using the post-correction exposure patterns REP according to the present embodiment.

Even when a distortion is not caused in any of the first substrate P1A and the second substrate P2A, a distortion may be caused at the time of bonding these substrates. Accordingly, when a distortion is not caused in any substrate and a distortion is caused at the time of bonding, it is possible to more appropriately perform bonding by using the bonding method according to the present embodiment.

FIG. 6(B) is a diagram illustrating a problem in the related art. In the example illustrated in the drawing, a distortion is caused in the first substrate P1B, and bonding failure occurs. As can be apparently seen from the drawing, a distortion is caused in the first substrate P1B. Specifically, the conductor C121 and the conductor C221 in the left part of the drawing are bonded to each other, mismatch between the conductor C121 and the conductor C221 is accumulated to the right in the drawing, and the conductor C121 and the conductor C122 are separated from each other at points indicated by reference signs A1 and A2. When it is intended to bond the first substrate P1B and the second substrate P2B in this state, the conductor C121 and the conductor C221 mismatch at the points indicated by reference signs A1 and A2, and bonding failure occurs. Therefore, the exposure apparatus 100 according to the present embodiment resolves the bonding failure by correcting the exposure pattern EP for the uppermost layer of the second substrate P2.

FIG. 6(C) is a diagram schematically illustrating an example in which the uppermost layer of the second substrate P2C is exposed to light using a post-correction exposure pattern REP by the exposure apparatus 100 according to the present embodiment. As can be apparently seen from the drawing, the first layer L1 which is the uppermost layer of the second substrate P2C is corrected. Specifically, the conductor C221 extends to the right side in the drawing and is connected to the conductor C221. Particularly, even at the points indicated by reference signs A1 and A2 at which the conductor C121 and the conductor C221 are separated from each other in the example illustrated in FIG. 6(B), the conductor C221 extends to the right side in the drawing and thus is connected in the example illustrated in FIG. 6(C).

That is, according to the present embodiment, the second substrate L2 includes a plurality of layers, and the exposure control unit 140 performs control for exposing the uppermost layer (uppermost layer) of the second substrate P2 to light.

### [Conclusion of First Embodiment]

As described above, according to the present embodiment, the exposure apparatus 100 includes the substrate information acquiring unit 110 to acquire substrate information SI which is position information used to form a structure on a substrate P, includes the exposure pattern acquiring unit 120 to acquire information on a desired exposure pattern EP, includes the determination unit 130 to generate a post-correction exposure pattern REP on the basis of the acquired substrate information SI and the acquired exposure pattern EP, and performs control for exposing the substrate P to light on the basis of the generated post-correction exposure pattern REP.

Here, the substrate information SI is information which is acquired before exposing the substrate P to light. Accordingly, the exposure apparatus 100 can correct a position at which a structure is to be formed before exposing the substrate P to light. As a result, according to the substrate processing system 10, it is possible to accurately and appropriately bond a first substrate P1 and a second substrate P2.

According to the aforementioned embodiment, the substrate information SI is information which is acquired as a result of measurement of the structure formed on the first substrate P1 exposed to light by a first exposure apparatus other than the exposure apparatus 100. In other words, the exposure apparatus 100 exposes a second substrate P2 which is a substrate other than the first substrate P1 and exposed by the other exposure apparatus. That is, according to the present embodiment, the exposure apparatus for exposing the first substrate P1 to light and the exposure apparatus for exposing the second substrate P2 to light are different apparatuses.

Accordingly, according to the present embodiment, it is possible to accurately and appropriately bond substrates in which distortions having different features are caused using exposure apparatuses having different characteristics.

According to the present embodiment, the substrate information SI in the exposure apparatus 100 is information which is obtained by measuring position information of a structure formed on the surface of the substrate P of which a final layer has been exposed to light in advance. That is, the substrate information SI is information which is obtained as a result of measurement after the first substrate P1 has been exposed to light by the first exposure apparatus.

Accordingly, according to the present embodiment, it is possible to correct an exposure pattern EP of one substrate P according to a distortion of the other substrate P to be bonded. As a result, according to the present embodiment, it is possible to accurately and appropriately bond the substrates.

In the exposure apparatus 100 according to the aforementioned embodiment, the second substrate P2 includes a plurality of layers. The exposure apparatus 100 exposes an uppermost layer of the plurality of layers of the second substrate P2 to light. Accordingly, according to the present embodiment, since bonding mismatch can be resolved by exposure correction of only the uppermost layer, it is possible to easily correct the exposure pattern EP.

According to the aforementioned embodiment, since the uppermost layer of the plurality of layers of the second substrate P2 is exposed to light, intermediate layers do not require correction. Accordingly, according to the present embodiment, it is possible to easily manufacture a substrate P.

According to the aforementioned embodiment, the exposure apparatus 100 corrects the exposure pattern EP on the basis of a predetermined approximate expression. Accordingly, according to the present embodiment, it is possible to easily correct the exposure pattern EP on the basis of the substrate information SI.

### Second Embodiment

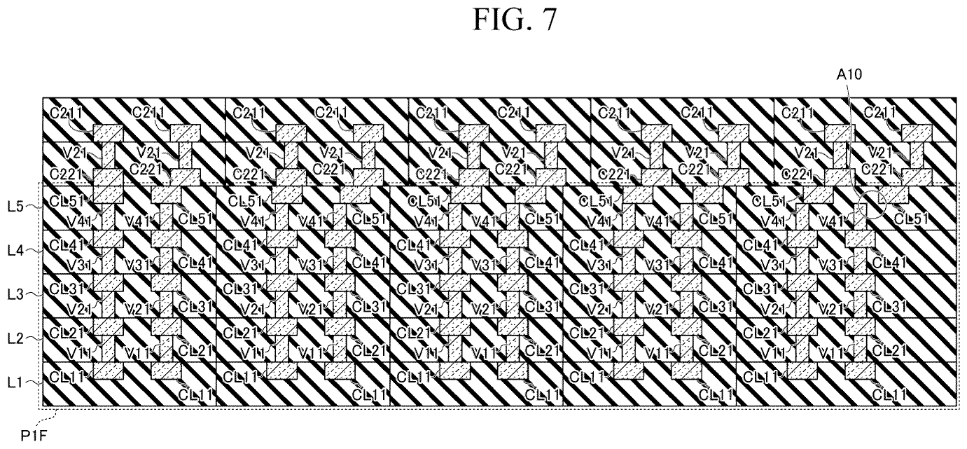

A second embodiment will be described below with reference to FIGS. 7 to 9. The second embodiment is different from the first embodiment in that the exposure apparatus 100 corrects one or more intermediate layers in addition to the uppermost layer. The same constituents as described above in the first embodiment will be referred to by the same reference signs, and thus description thereof may be omitted.

FIG. 7 is a diagram illustrating a problem to be solved by the second embodiment. A problem to be solved by the second embodiment will be described below with reference to the drawing.

The example illustrated in FIG. 7 is an example in which a distortion cannot be resolved by correcting only the uppermost layer. As illustrated in the drawing, when correction for only a fifth layer L5 which is the uppermost layer is performed, Patterns in the corrected fifth layer L5 and a fourth layer L4 which is a lower layer may be separated from each other. Particularly, at a point indicated by reference sign A10, a conductor C211 and a conductor CL51 mismatch, and bonding failure occurs.

In addition to the example in which the patterns of the fifth layer L5 and the fourth layer L4 are separated from each other, an unintentional short circuit may be formed.

In this way, in the first embodiment, since correction for only the uppermost layer is performed, a large distortion may not be able to be corrected. In the second embodiment, it is intended to solve this problem.

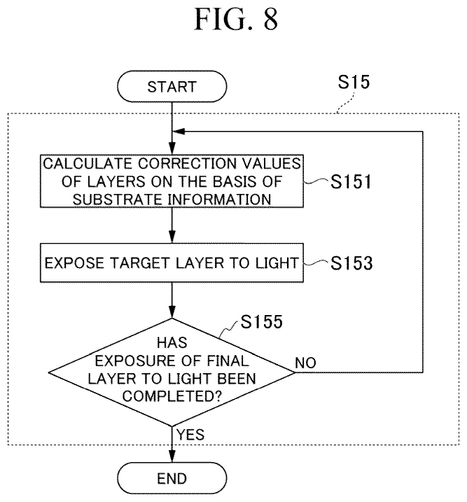

FIG. 8 is a flowchart illustrating an example of a series of operations that are performed by the exposure apparatus according to the second embodiment. An example of a series of operations performed by the exposure apparatus 100 according to the second embodiment will be described below with reference to the drawing. The operations described below with reference to the drawing are details of Step S15 described above with reference to FIG. 5.

In the example described below with reference to the drawing, it is assumed that a certain pattern is formed in a lowermost layer of the second substrate P2 in advance. When a certain pattern is formed on the second substrate P2 in advance, large modification cannot be performed and thus correction for each layer is stepwise performed.

When no pattern is formed in the lowermost layer, an amount of correction is not limited, and thus large modification can be performed on the lowermost layer. Above all, an amount of correction even in such a lowermost layer may be limited according to an amount of correction in the exposure apparatus or an exposure apparatus load corresponding to the amount of correction of the exposure apparatus.

(Step S151) The determination unit 130 calculates a correction value for each layer on the basis of substrate information SI. In other words, the determination unit 130 generates a post-correction exposure pattern REP for each layer. The substrate information SI may be, for example, a result of measurement of position information of a structure formed on the surface of a first substrate P1 using the measuring apparatus 200.

In the present embodiment, since correction which cannot be performed through only correction of a final layer is performed, a necessary amount of correction is divided by layers and correction is gradually performed. That is, the determination unit 130 calculates a correction value for each layer such that the final layer is bonded to another substrate at an appropriate position.

The determination unit 130 may further include a comparison unit which is not illustrated and thus identify a layer to be corrected out of a plurality of layers of a second substrate P2 on the basis of a result of comparison by comparing wiring information included in the exposure pattern EP with a predetermined threshold value. The determination unit 130 determines an exposure pattern EP which is a post-correction exposure pattern by correcting the identified layer.

(Step S153) The exposure control unit 140 exposes a target layer of the second substrate P2 which is different from the first substrate P1 on the basis of the post-correction exposure pattern REP calculated by the determination unit 130. In the present embodiment, the second substrate P2 includes a plurality of layers, and the exposure apparatus 100 performs exposure from the lowermost layer of the plurality of layers included in the second substrate P2. In other words, the exposure control unit 140 performs control for exposing the lowermost layer of the second substrate P2 to light.

(Step S155) When exposure of a final layer has not been completed (that is, Step S153: NO), the exposure control unit 140 causes the process flow to proceed to Step S151. That is, the exposure control unit 140 of the exposure apparatus 100 performs control for exposing the plurality of layers of the second substrate P2 to light by repeatedly performing Steps S151 to S155. Repetition of Steps S151 to S155 is not limited to repetition of an exposure process and means that processes such as resist application, exposure, development, insulating film deposition, etching, metal deposition, and chemical mechanical polisher (CMP) are also repeated. When the correction value of Step S151 is calculated while repeating these processes, it is preferable to measure an exposed uppermost layer of the second substrate P2 and calculate the correction value in consideration of the measured information in addition to information of the first substrate P1.

When exposure of the final layer has been completed (that is, Step S153: YES), the exposure control unit 140 ends the process flow.

Here, out of a plurality of layers included in a substrate P, a pattern width of a pattern of a lower layer may be small and the pattern width may increase toward an upper layer. Regarding a pattern for each layer corrected by the determination unit 130, an amount of correction for an upper layer can be set to be larger than that for a lower layer. That is, the determination unit 130 corrects an exposure pattern for exposing a first layer L1 (a first layer) to light and an exposure pattern for exposing a second layer L2 (a second layer) higher than the first layer L1 out of the plurality of layers included in the second substrate P2 to light. A correction value for the second layer L2 can be set to be larger than the correction value for the first layer L1.

Out of a plurality of layers included in a substrate P, patterns may be densely arranged in a certain layer or patterns may be coarsely arranged in another layer. In this case, a layer with coarse patterns may be corrected. In this case, it is possible to appropriately perform correction in a high degree of freedom in correction.

Out of a plurality of layers included in a substrate P, a design rule may differ depending on the layers, and there may be a layer with a strict design rule and a layer with a loose design rule. In this case, a layer with a loose design rule may be corrected. In this case, it is possible to appropriately perform correction in a high degree of freedom in correction.

In this way, since a degree of freedom in correction may differ depending on the layers, the determination unit 130 may include a comparison unit which is not illustrated to determine a layer to be corrected on the basis of whether wiring information included in the exposure pattern EP is equal to or greater than a predetermined threshold value. In this case, the comparison unit compares wiring information included in the exposure pattern EP with a predetermined threshold value. The determination unit 130 corrects an identified layer out of a plurality of layers included in the second substrate P2 on the basis of a result of comparison from the comparison unit.

FIG. 9 is a diagram schematically illustrating an example of a substrate which has been exposed to light by the exposure apparatus according to the second embodiment. Advantages when exposure is performed using a post-correction exposure pattern REP by the exposure apparatus 100 according to the second embodiment will be described below with reference to FIG. 9. FIG. 9 is a diagram schematically illustrating a substrate P1G when correction is divisionally performed on layers.

In the example described below with reference to FIG. 9, the substrate PIG includes first to fifth layers L1 to L5. The substrate PIG includes a plurality of conductors CL11 in the first layer L1, includes a plurality of conductors CL21 in the second layer L2, includes a plurality of conductors CL31 in the third layer L3, includes a plurality of conductors CL41 in the fourth layer L4, and includes a plurality of conductors CL51 in the fifth layer L5. The first layer L1 and the second layer L2 are connected via a contact hole V11, the second layer L2 and the third layer L3 are connected via a contact hole V21, the third layer L3 and the fourth layer L4 are connected via a contact hole V31, and the fourth layer L4 and the fifth layer L5 are connected via a contact hole V41.

In the example illustrated in FIG. 9, since a necessary amount of correction is divided into the first layer L1 which is a lowermost layer to the fifth layer L5 and correction is performed thereon, a conductors CL51 and a conductor CL52 in the fifth layer are not separated from each other, and a short circuit is not formed. That is, appropriate correction is performed.

In this way, according to the second embodiment, it is possible to perform correction which is not possible using only the uppermost layer by dividing a necessary amount of correction into the layers and performing correction thereon.

### [Conclusion of Second Embodiment]

As described above, according to the present embodiment, the exposure apparatus 100 performs control for exposing a lower most layer to light out of a plurality of layers included in a substrate P. Accordingly, according to the present embodiment, it is possible to appropriately and accurately correct a distortion which cannot be corrected using only the uppermost layer.

According to the aforementioned embodiment, the exposure apparatus 100 performs control for exposing a plurality of layers to light as well as the uppermost layer out of the plurality of layers included in the substrate P. Accordingly, according to the present embodiment, it is possible to gradually correct pattern positions by a plurality of layers and to appropriately and accurately correct a distortion which cannot be corrected using only the uppermost layer.

In the exposure apparatus 100 according to the aforementioned embodiment, the correction value for a lower layer out of a plurality of layers included in a substrate P is larger than the correction value for an upper layer. That is, according to the present embodiment, the determination unit 130 generates the post-correction exposure pattern REP such that an amount of correction increases gradually sequentially from the lowermost layer.

In semiconductor manufacturing technology, a pattern width in a lower layer may be smaller, and the pattern width may increase toward an upper layer. Accordingly, according to the present embodiment, the exposure apparatus 100 performs more correction on an upper layer with a larger pattern width than that in a lower layer with a smaller pattern width, whereby it is possible to appropriately perform correction.

According to the aforementioned embodiment, the exposure apparatus 100 includes a comparison unit with which is not illustrated to compare wiring information included in an exposure pattern EP with a predetermined threshold value. The determination unit 130 performs correction on an identified layer out of a plurality of layers included in a substrate P on the basis of a result of comparison from the comparison unit.

Accordingly, according to the present embodiment, it is possible to identify a layer suitable for correction and to correct the identified layer.

An amount of correction for a layer identified through comparison in the comparison unit may be determined on the basis of a difference from the predetermined threshold value.

When a distortion of a substrate P is large and it is difficult to correct the distortion, the exposure apparatus 100 may add a correction layer for correction.

### Third Embodiment

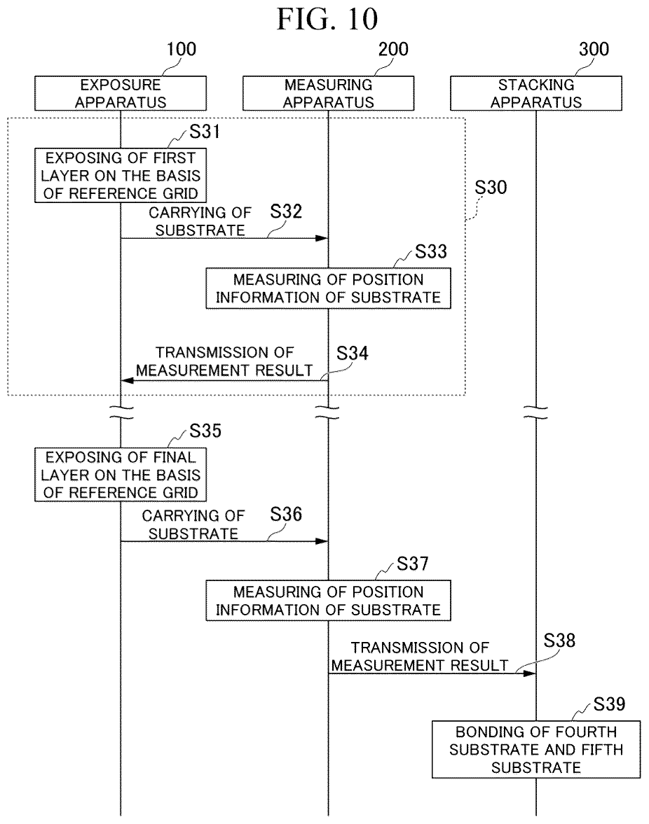

A third embodiment will be described below with reference to FIG. 10. The third embodiment is different from the aforementioned embodiments in that substrate information SI includes information on a position of a reference grid RG formed on a reference substrate or a reference wafer. The reference grid RG may be included in the structure according to the aforementioned embodiments. The reference grid RG is a grid serving as a reference for an exposure pattern in the exposure apparatus 100 and is information which is used for the exposure apparatus 100 to correct an exposure pattern. The reference grid RG is not a reference grid of a reference substrate or a reference wafer but may be a grid of a substrate P of which distortions and the like have been corrected. In the illustrated example, the reference grid RG may be a grid having a distortion for cancelling a distortion predicted to be caused in a subsequent process (for example, a bonding process using the stacking apparatus 300) or a part thereof. In the description of the present embodiment, an upper wafer may be referred to as a fourth substrate P4, and a lower wafer may be referred to as a fifth substrate P5. The fourth substrate P4 and the fifth substrate P5 include a plurality of layers. The same constituents as described above in the aforementioned embodiments will be referred to by the same reference signs, and thus description thereof may be omitted.

Information on the reference grid RG is determined by determining a layout of shots on a wafer. Specifically, a shot size and a shot pitch are determined at a time point at which design of a mask layout has been completed, and the reference grid RG on the wafer is determined by additionally determining a layout of shots on the wafer.

For example, the information on the reference grid RG may be registered in a server device which is not illustrated along with recipe information for each product model. The information on the reference grid RG may be acquired as substrate information SI when an exposure recipe is transmitted from the server device to the exposure apparatus 100. The exposure apparatus 100 performs correction computation on the basis of the acquired information on the reference grid RG. After the correction computation has been performed in the server device, an exposure recipe including correction information may be transmitted to the exposure apparatus 100.

When the reference grid RG is set to have a distortion for cancelling a distortion predicted to be caused in a subsequent process (for example, a bonding process) or a part thereof, the exposure apparatus 100 (or the server device) may set the reference grid RG using additional information which will be described below.

First, it is conceivable that bonding distortion information of a stacked wafer (a stacked substrate) which has been stacked in the past be used. In this case, a stacked wafer of a similar product model may be referred to. It is conceivable that test substrates be bonded once, an actual bonding distortion be ascertained, and the reference grid RG be corrected using that information.

Second, it is also conceivable that an arrangement for which a distortion caused in a wafer due to a stress or the like in the course of wafer manufacturing is cancelled in advance in the exposure step such that a shape of shot areas in substrates P immediately before being bonded are substantially the same as the reference grid RG be used as the reference grid RG. In this case, similarly to the bonding distortion, it is conceivable to perform correction using a stress in the course of wafer manufacturing or distortion information acquired from a stacked wafer which was stacked in the past or information acquired by actually preparing a wafer.

Third, when the reference grid RG is set to be intentionally distorted according to the bonding distortion or the distortion in the course of wafer manufacturing as described above, it is conceivable that a reference grid RG for an upper wafer and a reference grid RG for a lower wafer be independently used.

The information on a reference grid RG may be changed, for example, at the timing at which a type or a pattern of a wafer is changed. When a reference grid RG is not changed for devices of different models, but a reference grid RG of the same model are corrected according to information acquired in the course of actually manufacturing a wafer (for example, a bonding distortion or a distortion based on a stress in the course of manufacturing), the exposure pattern may be adjusted to an exposure pattern corresponding to the corrected reference grid RG, for example, on the basis of the function of the exposure apparatus 100 including lens magnification control without changing a mask.

The measuring apparatus 200 measures an error from the reference grid RG whenever each layer is exposed to light by the exposure apparatus 100 and corrects the error at the time of exposing a next layer to light. In the present embodiment, it is possible to curb an obstacle (for example, a short-circuit between conductors) which is generated due to great correction of a final layer by correcting the difference from the reference grid RG for each layer. Since the fourth substrate P4 and the fifth substrate P5 are corrected on the basis of the reference grids RG, positional mismatch which cannot be corrected is not caused at the time of bonding the substrates.

Here, the reference grid RG for an upper wafer and the reference grid RG for a lower wafer may be made to be different from each other. The reference grid RG for an upper wafer is referred to as a first reference grid RG1, and the reference grid RG for a lower wafer is referred to as a second reference grid RG2. That is, the reference grids RG include the first reference grid RG1 for correcting an exposure pattern EP for exposing the fourth substrate P4 to light and the second reference grid RG2 for correcting an exposure pattern EP for exposing the fifth substrate P5 to light.

Here, the first reference grid RG1 and the second reference grid RG2 have a predetermined relationship. The predetermined relationship is, for example, a mirror image relationship. That is, the second reference grid RG2 may be a mirror image of the first reference grid RG1.

When the first exposure apparatus for exposing an upper wafer to light and the second exposure apparatus for exposing a lower wafer to light or when the upper wafer and the lower wafer are exposed to light in different steps, different reference grids RG may be used in the exposure apparatuses or steps.

FIG. 10 is a sequence diagram illustrating an example of a series of operations that are performed by the substrate processing system according to the third embodiment. A series of operations in the substrate processing system 10 according to the third embodiment will be described below with reference to the drawing. In the present embodiment, the stacking apparatus 300 bonds the fourth substrate P4 and the fifth substrate P5. The fourth substrate P4 and the fifth substrate P5 are manufactured through the same processes. An example of the processes of manufacturing the fourth substrate P4 will be described below with reference to the drawing. The fifth substrate P5 is manufactured through the same processes.

(Step S31) The exposure apparatus 100 performs first exposure on the fourth substrate P4. A structure is formed on a substrate surface by forming a latent image on the fourth substrate P4 through the first exposure using the exposure apparatus 100 and then performing development or the like thereon using other processing apparatuses which are not illustrated.

(Step S32) The fourth substrate P4 in which a structure has been formed on the substrate surface is carried to the measuring apparatus 200 using a predetermined method.

(Step S33) The measuring apparatus 200 measures position information of the structure formed on the substrate surface of the carried fourth substrate P4. Here, the measuring apparatus 200 measures a distortion caused in the fourth substrate P4 and a difference from the reference grid RG.

(Step S34) The measuring apparatus 200 transmits the result of measurement as substrate information SI to the exposure apparatus 100.

The processes of Steps S31 to S34 are also referred to as Step S30. Step S30 is a process of forming one layer out of a plurality of layers included in the fourth substrate P4. That is, Step S30 is repeated by the number of layers included in the fourth substrate P4.

In exposure of a second layer or layers subsequent thereto, the result of measurement from the measuring apparatus 200 after the immediately previous exposure is reflected. That is, in the present embodiment, the measuring apparatus 200 measures a difference from a reference grid RG whenever one layer is exposed to light, and the exposure apparatus 100 adds correction for not accumulating the difference from the reference grid RG and performs exposure.

A specific operation of the exposure apparatus 100 for adding correction for not accumulating the difference from the reference grid RG and performing exposure will be described below. The exposure pattern acquiring unit 120 acquires an exposure pattern EP for exposing the fourth substrate P4 to light. The determination unit 130 corrects the exposure pattern EP for exposing the fourth substrate P4 to light on the basis of the reference grid RG. The exposure control unit 140 performs control for exposing the fourth substrate P4 to light on the basis of the corrected exposure pattern EP for exposing the fourth substrate P4 to light. The exposure control unit 140 performs control for exposing a plurality of layers included in the fourth substrate P4 to light.

Since Step S30 is repeatedly performed on intermediate layers, description thereof will be omitted, and processes after the final layer has been exposed to light will be described.

(Step S35) The exposure apparatus 100 performs exposure of a final layer on the fourth substrate P4. The exposure apparatus 100 performs exposure on the basis of the exposure pattern EP which has been corrected on the basis of the result of measurement of a lower layer just below the final layer. A structure is formed on the substrate surface by forming a latent image on the fourth substrate P4 through the exposure using the exposure apparatus 100 and then performing development or the like thereon using other processing apparatuses which are not illustrated.

(Step S36) The fourth substrate P4 in which a structure has been formed on the substrate surface is carried to the measuring apparatus 200 using a predetermined method.

(Step S37) The measuring apparatus 200 measures position information of the structure formed on the substrate surface of the carried fourth substrate P4. Specifically, the measuring apparatus 200 measures a distortion caused in the fourth substrate P4 and a difference from the reference grid RG.

(Step S38) The measuring apparatus 200 transmits the result of measurement as substrate information SI to the stacking apparatus 300.

(Step S39) The fourth substrate P4 is carried to the stacking apparatus 300. The stacking apparatus 300 bonds two substrates by stacking the carried fourth substrate P4 and the fifth substrate P5.

The fifth substrate P5 may be exposed to light by the exposure apparatus 100 having exposed the fourth substrate P4 to light. In this case, the exposure apparatus 100 performs exposure on the fifth substrate P5 which is a substrate to be bonded to the fourth substrate P4. The fifth substrate P5 is different from the fourth substrate P4. Specifically, the exposure pattern acquiring unit 120 acquires an exposure pattern EP for exposing the fifth substrate P5 other than the fourth substrate P4 to light. The determination unit 130 corrects the exposure pattern EP for exposing the fifth substrate P5 to light on the basis of the second reference grid RG2. The exposure control unit 140 performs control for exposing the fifth substrate P5 to light on the basis of the corrected exposure pattern EP for exposing the fifth substrate P5 to light. The exposure control unit 140 performs control for exposing a plurality of layers included in the fifth substrate P5 to light.

### [Conclusion of Third Embodiment]

As described above, according to the present embodiment, the exposure apparatus 100 corrects an exposure pattern EP on the basis of substrate information SI which is information obtained by measuring a difference from a reference grid RG. The exposure apparatus 100 corrects the exposure pattern EP such that the difference from the reference grid RG is cancelled for each layer. Accordingly, according to the present embodiment, since a distortion is cancelled on the basis of the reference grid RG, great large mismatch from another substrate to be bonded is not caused. As a result, according to the present embodiment, it is possible to appropriately bond the substrates.

According to the present embodiment, the reference grid RG includes a first reference grid RG1 for correcting one substrate to be bonded and a second reference grid RG2 for correcting the other substrate. The first reference grid RG1 and the second reference grid RG2 have a mirror image relationship. Accordingly, it is possible to bond the surfaces of two substrates P corrected on the basis of the reference grid RG.

The reference grid RG is a grid having a distortion for canceling a distortion predicted to be caused in a subsequent process. Accordingly, according to the present embodiment, it is possible to bond the surfaces of two substrates P even when the grid is not an ideal grid.

According to the present embodiment, correction based on the reference grid RG is performed on each of a plurality of layers. Accordingly, according to the present embodiment, even when the substrates P include a plurality of layers, distortions are not accumulated, and great positional mismatch from another substrate to be bonded is not caused. As a result, according to the present embodiment, it is possible to appropriately bond the substrates.

According to the present embodiment, since substrates P to be bonded are manufactured on the basis of the reference grid RG, it is possible to start manufacturing without waiting for completion of the other substrate P to be bonded. Here, a period of about several weeks to several months may be required for manufacturing a substrate P. Accordingly, according to the present embodiment, it is possible to simultaneously start manufacturing of an upper wafer and a lower wafer without waiting for several weeks to several months.

The exposure apparatus 100 may perform correction based on the reference grid RG using a technique according to the third embodiment on at least one layer of a plurality of layers included in a substrate P and perform correction based on position information of the other substrate P to be bonded (which includes a difference between the result of measurement and the reference grid RG) using a technique according to the first embodiment on at least one of the other layers. For example, the technique according to the third embodiment is used for an intermediate layer, and the technique according to the first embodiment is used for a final layer. The substrate processing system 10 can more accurately bond substrates by performing correction based on the position information of the other substrate P of which only the uppermost layer is to be bonded.

The exposure apparatus 100 may perform correction based on the position information of the other substrate P to be bonded on a specific layer out of the intermediate layers in addition to the uppermost layer. With this configuration, it is possible to manufacture a substrate corresponding to the other substrate to be bonded and to more accurately bond the substrates.

In this case, by measuring an alignment mark AM in an uppermost layer or a specific layer of intermediate layers of the fourth substrate P4 using the measuring apparatus 200, calculating a difference from the reference grid RG, measuring an alignment mark AM in an uppermost layer or a specific layer of intermediate layers of the fifth substrate P5 using the measuring apparatus 200, calculating the difference from the reference grid RG, and comparing the results of measurement and the differences, an exposure position of the fifth substrate P5 may be corrected on the basis of the result of measurement of the fourth substrate P4 or an exposure position of the fourth substrate P4 may be corrected on the basis of the result of measurement of the fifth substrate P5.

The exposure apparatus 100 may perform correction based on the reference grid RG on a layer with a loose design rule and perform exposure based on a layer just below on a layer with a strict design rule. By employing this configuration, the exposure apparatus 100 can expose a layer requiring a strict design rule to light.

In the aforementioned embodiment, it is assumed that an exposure pattern EP is corrected such that a difference from the reference grid RG is cancelled for each layer. According to this example, it is possible to cancel a distortion caused in the middle steps for each layer. However, the present embodiment is not limited to this example. For example, an average value of distortions caused in the middle steps may be permitted, and uneven distortions for each wafer may be corrected for each layer. That is, distortions caused in the middle steps may be corrected in advance at the time of exposure of a first layer, and unevenness for each wafer may be corrected for each layer.

When unevenness for each wafer is corrected for each layer, reference grids which are different for the layers may be used.

### Fourth Embodiment

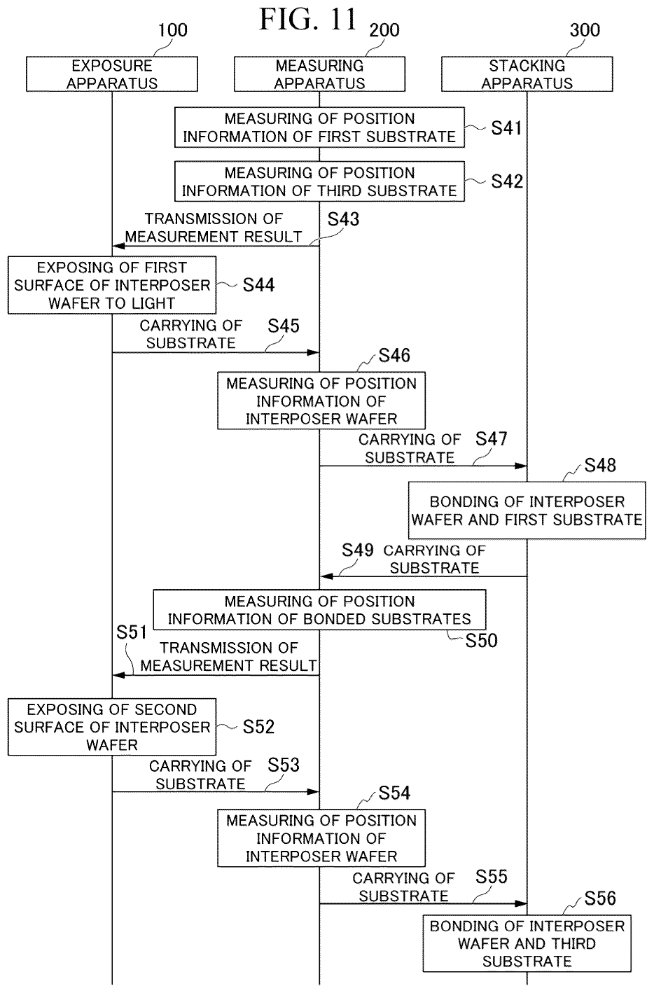

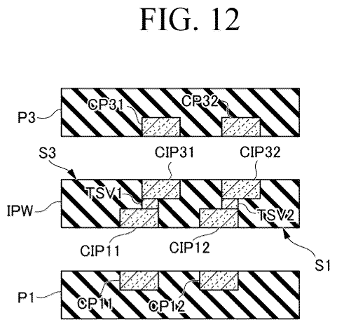

A fourth embodiment will be described below with reference to FIGS. 11 and 12. The fourth embodiment is different from the aforementioned embodiments in that the surface of a first substrate P1 and the surface of a second substrate P2 are bonded with an interposer wafer IPW interposed therebetween instead of directly bonding the surfaces. An interposer wafer IPW is a substrate which is inserted between two substrates to be bonded.

Here, when two substrates to be bonded have great distortions or when the two substrates are exposed to light up to the final layer, it may be difficult to bond the substrates. In the present embodiment, even when it is difficult to bond the substrates, it is intended to appropriately bond the substrates by inserting an interposer wafer IPW therebetween.

In the following description, the upper wafer may be referred to as a first substrate P1, the lower wafer may be referred to as a third substrate P3, and the interposer wafer IPW inserted between the first substrate P1 and the third substrate P3 may be referred to as a second substrate P2. The interposer wafer IPW may be simply referred to as an interposer.

FIG. 11 is a sequence diagram illustrating an example of a series of operations that are performed by the substrate processing system according to the fourth embodiment. A series of operations in the substrate processing system 10 according to the fourth embodiment will be described below with reference to the drawing. In the present embodiment, the stacking apparatus 300 bonds the first substrate P1 and the third substrate P3 by bonding the first substrate P1 to one surface of the second substrate P2 which is the interposer wafer IPW and bonding the third substrate P3 to the other surface of the second substrate P2. The first substrate P1 and the third substrate P3 may be manufactured by the same exposure apparatus 100 or may be manufactured by different exposure apparatuses. The first substrate P1 and the third substrate P3 may be manufactured in different fabrications. In the present embodiment, it is assumed that the first substrate P1 is exposed to light by a first exposure apparatus and the second substrate P2 is exposed to light by a second exposure apparatus.

(Step S41) The measuring apparatus 200 measures position information of a structure formed on the substrate surface of the first substrate P1.

(Step S42) The measuring apparatus 200 measures position information of a structure formed on the substrate surface of the third substrate P3.

(Step S43) The measuring apparatus 200 transmits the results of measurement as substrate information SI to the exposure apparatus 100.

(Step S44) The exposure apparatus 100 acquires the substrate information SI including the results of measurement from the measuring apparatus 200. Specifically, the substrate information acquiring unit 110 acquires first substrate information SI1 acquired as a result of measurement of the structure formed on the first substrate P1 exposed to light by the first exposure apparatus.

The exposure apparatus 100 exposes a first surface S1 of the interposer wafer IPW to light on the basis of the acquired substrate information SI. Specifically, the exposure apparatus 100 performs control for exposing one surface (the first surface S1) of the interposer wafer IPW to light on the basis of the position information of the structure formed on the substrate surface of the first substrate P1 included in the substrate information SI.

(Step S45) After the first surface S1 of the interposer wafer IPW has been exposed to light, processes such as development, insulating film deposition, etching, metal deposition, and CMP are performed thereon. Thereafter, the interposer wafer IPW is carried to the measuring apparatus 200 using a predetermined method.

(Step S46) The measuring apparatus 200 measures position information of the structure formed on the substrate surface which is the first surface S1 of the interposer wafer IPW.

(Step S47) The first substrate P1 and the interposer wafer IPW are carried to the stacking apparatus 300 using a predetermined method.

(Step S48) The stacking apparatus 300 bonds the interposer wafer IPW and the first substrate P1. Specifically, the stacking apparatus 300 bonds the first substrate P1 and the first surface S1 of the interposer wafer IPW.

(Step S49) The first substrate P1 and the interposer wafer IPW are bonded to each other and then are carried to the measuring apparatus 200.

(Step S50) The measuring apparatus 200 measures position information of the structure formed on the substrate surface which is a third surface S3 of a substrate which is formed by bonding the interposer wafer IPW and the first substrate P1. The third surface S3 is a rear surface opposite to the first surface S1.

(Step S51) The substrate which is formed by bonding the interposer wafer IPW and the first substrate P1 is carried to the measuring apparatus 200.

(Step S52) The exposure apparatus 100 acquires substrate information SI including the results of measurement from the measuring apparatus 200. Specifically, the substrate information acquiring unit 110 acquires substrate information of the substrate which is formed by bonding the interposer wafer IPW and the first substrate P1 and third substrate information SI2 which is substrate information of the third substrate P3. The third substrate information SI2 is information which is acquired as a result of measurement of the structure formed on the third substrate P3. The third substrate P3 may be exposed to light by the second exposure apparatus different from the first exposure apparatus or may be exposed to light by the same exposure apparatus.

The exposure apparatus 100 exposes the third surface S3 of the interposer wafer IPW to light on the basis of the acquired substrate information SI. Specifically, the exposure apparatus 100 exposes the other surface (the third surface S3) of the interposer wafer IPW to light on the basis of the position information of the structure formed on the substrate surface of the third substrate P3 included in the third substrate information SI2. That is, the exposure control unit 140 performs control for exposing the third surface S3 which is the opposite surface of the first surface S1 with a pattern based on the third substrate information SI2.

(Step S53) More specifically, positions of through-silicon vias (TSVs) and bonding electrodes are subjected to exposure and correction and re-adjusted to correspond to the third substrate P3 through insulating film deposition. Thereafter, TSVs are opened through etching, and metal is buried.

Thereafter, the interposer wafer IPW is carried to the measuring apparatus 200 using a predetermined method.

(Step S54) The measuring apparatus 200 measures position information of the structure formed on the substrate surface which is the third surface S3 of the interposer wafer IPW.

(Step S55) The third substrate P3 and the interposer wafer IPW bonded to the first substrate P1 are carried to the stacking apparatus 300 using a predetermined method.

(Step S56) The stacking apparatus 300 bonds the interposer wafer IPW bonded to the first substrate P1 and the third substrate P3. Specifically, the stacking apparatus 300 bonds the third substrate P3 and the third surface S3 of the interposer wafer IPW.

The interposer wafer IPW will be more specifically described below.

FIG. 12 is a diagram schematically illustrating an interposer wafer according to the fourth embodiment. The interposer wafer IPW will be more specifically described below with reference to the drawing. The interposer wafer IPW is inserted between the first substrate P1 and the third substrate P3.

For example, when the first substrate P1 and the third substrate P3 are directly bonded, the two substrates may not be able to be appropriately bonded depending on positions of the structures formed on the substrate surfaces. In this case, the interposer wafer IPW is also used to bond the two substrates.

A pattern based on the position of the structure formed on the surface of the first substrate P1 is formed on the first surface S1 which is one surface of the interposer wafer IPW. In the example illustrated in FIG. 12, a pattern corresponding to a conductor CP11 is formed as a conductor CIP11, and a pattern corresponding to a conductor CP12 is formed as a conductor CIP12.

A pattern based on the position of the structure formed on the surface of the third substrate P3 is formed on the third surface S3 which is the other surface of the interposer wafer IPW. In the example illustrated in the drawing, a pattern corresponding to a conductor CP31 is formed as a conductor CIP31, and a pattern corresponding to a conductor CP32 is formed as a conductor CIP32.

Regarding the patterns formed on the first surface S1 and the patterns formed on the third surface S3, the corresponding patterns are connected by the corresponding TSV. In the example illustrated in FIG. 12, the conductor CIP11 and the conductor CIP31 are connected by the TSV1, and the conductor CIP12 and the conductor CIP32 are connected by the TSV2.

By forming the interposer wafer IPW in this way, it is possible to appropriately bond the substrates with the interposer wafer IPW interposed therebetween even when the positions of the structures formed on the substrate surfaces of the first substrate P1 and the third substrate P3 mismatch due to a distortion and both substrates cannot be appropriately bonded to each other.

### [Conclusion of Fourth Embodiment]

As described above, according to the present embodiment, the substrate information acquiring unit 110 acquires position information on the surfaces of two substrates P which have been manufactured in advance. The exposure control unit 140 controls exposure on the basis of the acquired position information on the surfaces of the substrates P. That is, according to the present embodiment, it is possible to appropriately bond two substrates to be bonded using the stacking apparatus 300 even when positional accuracy between the two substrates is not high.

According to the present embodiment, the second substrate P2 is an interposer wafer IPW. That is, the exposure apparatus 100 exposes the interposer wafer IPW on the basis of position information on the surfaces of substrates P which have been manufactured in advance. Accordingly, according to the present embodiment, the substrate processing system 10 can bond two substrates of which positional accuracy between the substrate surfaces is not high using the interposer wafer IPW and using the stacking apparatus 300. As a result, according to the present embodiment, it is possible to appropriately bond substrates.

Here, the first substrate P1 and the third substrate P3 may be substrates which are manufactured through exposure using the exposure apparatus 100 described above in any of the first to third embodiments. That is, when a distortion which cannot be corrected using the techniques described above in the first to third embodiments occurs, the interposer wafer IPW described above in the fourth embodiment may be used. By using the techniques described above in the first to third embodiments based on the premise of use of the interposer wafer IPW, it is possible to loosen the positional accuracy when the upper wafer and the lower wafer are exposed to light.

In the aforementioned embodiment, it is assumed that wafers are bonded, but the present embodiment is not limited to this example. For example, a lower wafer is exposed to light and then diced, and the diced chips may be bonded to corresponding chips of an upper wafer. By employing this dicing and bonding, it is not necessary to perform alignment between wafers as a whole and it is possible to bond chips even when alignment between wafers as a whole is difficult.

All or some of the functions of the constituent units provided in the substrate processing system 10 according to the aforementioned embodiments may be realized by recording programs for realizing these functions on a computer-readable recording medium and causing a computer system to read and execute the programs recorded on the recording medium. The “computer system” mentioned herein includes an OS or hardware such as peripherals.

The “computer-readable recording medium” is a portable medium such as a flexible disk, a magneto-optical disc, a ROM, or a CD-ROM or a storage device such as a hard disk incorporated into a computer system. The “computer-readable recording medium” may include a medium that dynamically holds a program for a short time such as a communication line when the program is transmitted via a network such as the Internet or a communication circuit line such as a telephone line or a medium that holds a program for a predetermined time such as a volatile memory in a computer system serving as a server or a client in that case. The program may be a program for realizing some of the aforementioned functions or may be a program for realizing the aforementioned functions in combination with another program stored in advance in the computer system.

While an embodiment of the present invention has been described above in detail with reference to the drawings, any specific configuration is not limited to the above description, and various modifications in design or the like may be added thereto without departing from the gist of the invention.

### INDUSTRIAL APPLICABILITY

According to the present invention, it is possible to appropriately bond a plurality of substrates.

### REFERENCE SIGNS LIST

10 Substrate processing system
100 Exposure apparatus
200 Measuring apparatus
300 Stacking apparatus
110 Substrate information acquiring unit
120 Exposure pattern acquiring unit
130 Determination unit
140 Exposure control unit
P Substrate
AM Alignment mark
SI Substrate information
EP Exposure pattern
REP Post-correction exposure pattern
RG Reference grid
IPW Interposer wafer

1. A substrate processing system comprising:
a substrate information acquiring unit configured to acquire substrate information including position information of a structure which is located above a surface of a first substrate; and
a determination unit configured to determine an exposure condition for exposing a second substrate which is bonded to the first substrate to light on the basis of the acquired substrate information.

2. The substrate processing system according to claim 1, comprising a computation apparatus including the substrate information acquiring unit and the determination unit.

3. The substrate processing system according to claim 1, further comprising a measuring apparatus for measuring position information of the structure,
wherein the substrate information acquiring unit acquires the substrate information including the position information measured by the measuring apparatus.

4. The substrate processing system according to claim 3, further comprising a first exposure apparatus for exposing the first substrate to light,
wherein the measuring apparatus measures position information of the structure formed by causing the first exposure apparatus to expose a layer of photosensitive material layer above the surface of the first substrate to light.

5. The substrate processing system according to claim 4, further comprising a second exposure apparatus for exposing the second substrate to light, the second exposure apparatus being different from the first exposure apparatus,
wherein the second exposure apparatus exposes the second substrate to light on the basis of the substrate information including the position information of the structure.

6. The substrate processing system according to claim 1, wherein the second substrate includes a plurality of layers, and
wherein the determination unit determines the exposure condition for exposing an uppermost layer of the second substrate to light.

7. The substrate processing system according to claim 1, wherein the second substrate includes a plurality of layers, and
wherein the determination unit determines the exposure condition for exposing a lower layer of the second substrate to light.

8. The substrate processing system according to claim 6, wherein the determination unit determines a plurality of exposure conditions for exposing the plurality of layers of the second substrate to light.

9. The substrate processing system according to claim 1, further comprising a pre-correction exposure pattern acquiring unit configured to acquire preset pre- correction exposure patterns of the first substrate and the second substrate,
wherein the determination unit determines a post-correction exposure pattern by correcting the pre-correction exposure pattern on the basis of the substrate information.

10. The substrate processing system according to claim 9, further comprising a comparison unit configured to compare wiring information included in the exposure condition with a predetermined threshold value,
wherein the determination unit identifies a layer to be corrected out of a plurality of layers included in the second substrate on the basis of a result of comparison from the comparison unit and determines the post-correction exposure pattern to be formed in the identified layer.

11. The substrate processing system according to claim 8, wherein the determination unit determines the exposure condition for exposing a first layer out of a plurality of layers included in the second substrate to light and the exposure condition for exposing a second layer above the first layer to light, and
wherein a correction value for the first layer is greater than a correction value for the second layer.

12. The substrate processing system according to claim 1, wherein the substrate information acquiring unit acquires first substrate information including the position information of the structure and third substrate information including position information of a structure formed on a third substrate other than the first substrate, and wherein the determination unit determines an exposure condition based on the first substrate information for a first surface of the second substrate and determines an exposure condition based on the third substrate information for a second surface which is an opposite surface of the first surface.

13. The substrate processing system according to claim 12, wherein the second substrate is an interposer for bonding the first substrate and the third substrate.

14. The substrate processing system according to claim 1, further comprising a pre-correction exposure pattern acquiring unit configured to acquire a preset pre-correction first exposure pattern of the first substrate and a pre-correction second exposure pattern which is a preset exposure pattern of the second substrate,
wherein the structure includes a reference grid formed on a reference substrate, and
wherein the determination unit determines a post-correction first exposure pattern by correcting the pre-correction first exposure pattern on the basis of the reference grid and determines a post-correction second exposure pattern by correcting the pre-correction second exposure pattern on the basis of the reference grid.

15. The substrate processing system according to claim 14, wherein the reference grid includes a first reference grid for correcting the exposure condition for exposing the first substrate to light and a second reference grid for correcting the exposure condition for exposing the second substrate to light, and
wherein the second reference grid is a mirror image of the first reference grid. 16 (Original) The substrate processing system according to claim 14, wherein the first substrate and the second substrate include a plurality of layers, and
wherein the determination unit performs control for exposing the plurality of layers of the first substrate and the plurality of layers of the second substrate to light.

17. The substrate processing system according to claim 1, wherein the determination unit determines the exposure condition additionally on the basis of a predetermined approximate expression.

18. The substrate processing system according to claim 1, further comprising a stacking apparatus for overlapping the first substrate and the second substrate.

19. An exposure apparatus comprising an exposure control unit configured to expose a second substrate which is bonded to a first substrate to light on the basis of a substrate information including position information of a structure located above a surface of the first substrate.

20. A processing method comprising:
acquiring substrate information including position information of a structure which is located above a surface of a first substrate; and
determining an exposure condition for exposing a second substrate which is bonded to the first substrate to light on the basis of the acquired substrate information.

21. An exposure method comprising exposing a second substrate which is bonded to a first substrate to light on the basis of an exposure condition which is determined by the processing method according to claim 20.

22. An electronic device manufacturing method comprising:
an exposure method according to claim 21;
exposing the second substrate to light on the basis of the determined exposure condition; and
a stacking step of overlapping the first substrate and the second substrate.
